(19) United States
(12) Patent Application Publication
(10) Pub. No.: US 2008/0224127 A1
(43) Pub. Date: Sep. 18, 2008

(54) Gate dielectric structures, organic semiconductors, thin film transistors and related methods

(76) Inventors: Tobin J. Marks, Evanston, IL (US); Antonio Facchetti, Chicago, IL (US); Myung-Han Yoon, Cambridge, MA (US)

Correspondence Address: REINHART BOERNER VAN DEUREN S.C.;ATTN: LINDA KASULKE, DOCKET COORDINATOR, 1000 NORTH WATER STREET, SUITE 2100, MILWAUKEE, WI, 53202, US

(21) Appl. No.: 11/895,000

(22) Filed: Aug. 22, 2007

Related U.S. Application Data
(60) Provisional application No. 60/839,383, filed on Aug. 22, 2006.

(51) Int. Cl. H01L 51/40; H01L 51/00

(52) U.S. Cl. 257/40; 438/99; 257/E51.001

(57) ABSTRACT

Gate dielectric structures comprising an organic polymeric component, and organic semiconductor components, as can be used to fabricate thin film transistor devices.

This application claims priority benefit from provisional application Ser. No. 60/839,383 filed on Aug. 22, 2006, the entirety of which is incorporated herein by reference.

The United States government has certain rights to this invention pursuant to grant nos. STTR FA9550-05-C-0167, DMR-0076097, NCC 2-1363 and N00014-02-1-0909 from the AFOSR, NSF, NASA Institute for Nanoelectronics and Computing, and ONR, respectfully, to Northwestern University.

### BACKGROUND OF THE INVENTION

Field-effect-active organic semiconductors (OSCs) are of great interest for use in low-cost/disposable electronic products such as smart cards and radio frequency identification (RFID) tags, as well as in flexible display driver circuits, nonvolatile memories, and sensors. Indeed, amorphous and polycrystalline films of several OSCs exhibit hole or electron carrier mobilities comparable to or surpassing those of the inorganic semiconductor typically used for the aforementioned applications: amorphous hydrogenated silicon (a-Si:H). As an example, this material is currently used in fabricating thin film transistors (TFTs) for LC/LED displays and exhibits an electron carrier mobility of ˜1.0 cm²/Vs and Iₒₙ:I_{off} ratio >10⁶. For OSCs, such levels of TFT performance have been achieved by continuous innovation in molecular design as well as by careful control of vapor-/solution-phase film growth conditions via optimization of substrate temperature, solvent, deposition/solvent evaporation rate, material purity, etc. It is generally accepted that all of the aforementioned factors strongly influence semiconductor film microstructure, which in turn heavily influences charge transport. Other critical factors affecting overall semiconductor/device performance are chemical composition, surface functionalization, and surface morphology (roughness) of the gate dielectric.

Prior studies investigated the consequences for oligothiophene-base TFT response of employing various polymeric insulators, instead of SiO₂, as the gate dielectric layer. This work was followed by more recent investigations showing that implementation of appropriate insulators facilitates electron-transport for typical organic p-type semiconductors. More recently, it was also reported that certain insulators enable ambipolar transport for pentacene- and rubrene-based OTFTs (organic TFTs). Regarding OTFT dielectric-semiconductor interfacial effects, most studies have employed SiO₂ as the dielectric and pentacene as the semiconductor. It is generally accepted that gate dielectric surface roughness is an important parameter affecting OTFT electrical performance, and it was shown that rougher gate dielectric surfaces result in smaller pentacene grains and lower OTFT carrier mobilities. Note that several groups have explored correlations between pentacene grain size (tuned by varying film deposition rate, substrate temperature) and charge mobility, with most reporting increased mobility with increased pentacene grain size, although many aspects remain controversial. Very recently, the interplay between SiO₂ dielectric root-mean-square (rms) roughness, pentacene morphology, and charge transport was further studied using variable-temperature charge transport measurements.

In addition to dielectric morphology, the effects of dielectric surface chemical modification on device performance have been explored using self-assembled monolayers (SAMs). In general, simple SiO₂ hydrocarbon functionalization using octadecyltrichorosilane (OTS) or hexamethyldisilazane (HMDS) enhances the mobilities and lowers the off-currents of most OSCs. More recently, it was shown that threshold voltage as well as mobility can be modulated by SAM dipole induced built-in surface potentials. Although these results demonstrate the importance of controlling fundamental dielectric and/or interfacial properties for optimizing/controlling OSC charge transport efficiency, connections between dielectric bulk/surface chemistry, surface energy, dielectric-semiconductor interfacial morphology, and electrical properties are not completely clear, particularly for far less developed electron-transporting organic semiconductors.

An attractive alternative approach for modifying dielectric surfaces is to deposit a second layer, such as a spin-on polymer, on top. The major advantages of this approach are that, in contrast to SAM functionalization of oxide insulators, film deposition is not limited by the chemistry required for silane/phosphate coupling to the dielectric surface and different film thicknesses are readily accessed. Consequently, this methodology allows effective modification of bottom layer topography, hence planarization of rough dielectric surfaces while simultaneously fine-tuning the chemical properties of the dielectric surface via choice of the deposited polymer. Despite this great potential, to our knowledge investigations using this approach are sparse, limited to pentacene OTFTs. Accordingly, there is an on-going search in the art for alternate organic semiconductors for use in conjunction with such bilayer dielectric structures to utilize the benefits and advantages available therefrom.

### SUMMARY OF THE INVENTION

In light of the foregoing, it is an object of the present invention to provide a range of dielectric/semiconductor structures, thin film transistor devices and/or related methods, thereby overcoming various deficiencies and shortcomings of the prior art, including those outlined above. It will be understood by those skilled in the art that one or more aspects of this invention can meet certain objectives, while one or more other aspects can meet certain other objectives. Each objective may not apply equally, in all its respects, to every aspect of this invention. As such, the following objects can be viewed in the alternative with respect to any one aspect of this invention.

It can be an object of the present invention to provide a rational approach to the use of organic semiconductor components in conjunction with polymer-coated inorganic dielectric components, in the fabrication of thin film transistor devices.

It can be another object of the present invention to provide a range of organic semiconductor components for use with bilayer gate dielectric components to improve various transistor performance parameters.

Other objects, features, benefits and advantages of the present invention will be apparent from this summary and the following descriptions of certain embodiments, and will be readily apparent to those skilled in the art having knowledge of various thin film transistor devices, the dielectric and semiconductor components thereof and related assembly/fabrication techniques. Such objects, features, benefits and advantages will be apparent from the above as taken into conjunction with the accompanying examples, data, figures and all reasonable inferences to be drawn therefrom, alone or with consideration of the references incorporated herein.

In part, the present invention can be directed to a composite comprising a dielectric component comprising an inorganic oxide and an organic polymer film coupled thereto; and an organic non-acene semiconductor component coupled to the dielectric component. Non-acene semiconductor components can include those other than the fused aromatics (e.g., pentacene) employed with thin film transistor devices of the prior art. Without limitation, such semiconductor components can be independently selected from n-type, ambipolar and p-type semiconductors, as can be selected from the range of available oligothiophenes. Such compounds and related materials are known to those skilled in the art, use of which would be understood by those individuals made aware of this invention.

Without limitation, such semiconductor components and/or compounds useful in the context of the present invention can comprise various oligothiophene semiconductors and related compound structures such as but not limited to those described in U.S. Pat. Nos. 6,608,323 and 6,991,749; naphthalene semiconductors and related compound structures such as but not limited to those described in co-pending application Ser. No. 11/811,902, filed Jun. 12, 2007; perylene semiconductors and related compound structures such as but not limited to those described in co-pending application Ser. No. 11/043,814, filed Jan. 26, 2005; and other rylene semiconductors and related compound structures of the sort described in U.S. Pat. No. 7,138,522, each of which is incorporated herein in its entirety, together with various other tetralene and other n-type, p-type and ambipolar semiconductors/components and/or compounds as would be known to those skilled in the art made aware of this invention.

Regardless of semiconductor component, an inorganic oxide of such a dielectric component can be selected from any such oxide providing dielectric function. Without limitation, such a component can comprise silicon oxide. In certain such embodiments, a polymeric film coupled to a dielectric inorganic oxide can be selected from a polyvinyl alcohol and a polystyrene. Without limitation, in certain such embodiments, beneficial results are observed with an n-type oligothiophene semiconductor used in conjunction with a polystyrene insulating film.

Accordingly, in part, this invention can also be directed to a thin film transistor device comprising a dielectric component comprising an inorganic oxide and an organic polymer; and a non-acene organic semiconductor component coupled to the dielectric component. Such a device can be fabricated to provide various source and drain electrode configurations.

As illustrated below, this invention can also be directed to a method of using a dielectric polymer coating to affect charge mobility of an organic semiconductor component or one or more thin film transistor parameters. Such a method can comprise fabricating a thin film transistor device comprising an inorganic dielectric component and an organic semiconductor component; and coupling an insulating organic polymer component to the inorganic dielectric component. Choice of such an organic polymer, in conjunction with an inorganic dielectric, can reduce gate leakage and surface roughness. With respect to semiconductor performance, such an organic polymer can affect and/or enhance charge mobility. Without limitation, such benefits can be observed using a non-polar polymer component with an air-sensitive, n-type semiconductor. As to certain embodiments thereof, such benefits can be demonstrated using a polystyrene dielectric component in conjunction with an n-type oligothiophene semiconductor component.

### BRIEF DESCRIPTION OF THE FIGURES

FIG. 1. Chemical structure of the organic semiconductors (OSCs; left) and monolayers/polymers (right) employed in this study. The bottom gate OTFT device configuration is also shown (center).

FIG. 2. Tapping mode AFM images of: A. HMDS, B. spin-coated PS1, C. spin-coated PS4, and D. spin-coated PVA films on p⁺-Si/SiO₂ substrates. Insets show leakage current densities as a function of field for the indicated samples.

FIGS. 3A-B. A. Capacitance-frequency plots for bilayer p⁺-Si/SiO₂/polymer dielectrics measured on MIS structures (AC driving voltage=0.1 V, DC bias offset=−10 V). B. Inverse capacitance vs. polystyrene top layer thickness plot. Inset: Cᵢ vs. bias plot for PS1 (red) and PS4 (green).

FIGS. 4A-B. Comparison between the ID versus VG transfer plots (top, forward scan) and the corresponding square root of I_{D} versus V_{G} plots (bottom) for Bare- and PS1-based OTFTs for: A. n-channel (V_{G}<0 V) and B. p-channel (V_{G}>0 V) OTFT operation.

FIG. 5. Comparison of forward and return I_{D} versus V_{G} transfer plots for TFTs fabricated with the indicated OSC-dielectric combinations. Arrows denote gate bias sweep direction.

FIG. 6. A. Atomic force microscopic (˜0.5 ML, ˜2.0 nm thickness) and B. Scanning electron microscopic (˜50 nm thickness) images of DHCO-4T films grown on the indicated gate dielectrics. Scale bars denote 1 μm.

FIG. 7. Atomic force microscopic images of DHCO-4T films of different thickness grown on Bare and PS1 substrates. The insets show height profiles across indicated portions of the surface.

FIG. 8. AFM (0.5-˜1.5 monolayer) and SEM (50 nm thick) images of: A. DFH-4T and B. DH-4T films on the different dielectric substrates. Images in the lower row represent semiconducting films thicker than 0.5 monolayer. All scan areas are 2 μm×2 μm.

FIG. 9. Scanning electron microscopic images of: (A) P5 (pentacene) films on PS1 and PVA, and (B) CuFPc films on PS1 and PVA. Scale bar denotes 1 μm. Insets are images of water drops on semiconducting films for contact angle measurement.

FIG. 10. WAXRD θ-2θ scans for the indicated organic semiconductor (50 nm thick)-bilayer dielectric combinations.

FIG. 11. A. Histogram showing the mobility enhancement ratio η=μ_{X}/μ_{Bare} and B. Electrochemically-derived FMO energy levels for the organic semiconductors investigated in this study. The crosshatched bars denote semiconductor-dielectric combinations for which the largest variations in semiconductor film morphology are observed.

FIG. 12. Histogram showing the maximum estimated (according to eq. 3) interface trap densities (N^{max}ₜᵣₐₚ) for various semiconductor-dielectric combinations. The dotted plots for CuFPc denotes that this semiconductor exhibit substantial I_{off} currents indicating unintentional electron doping. Similarly, the crosshatched lines for DH-4T/PS-Ox and P5/PS-Ox are due to stress at the high I_{off} currents (extra mobile holes) recorded for these devices due to dielectric electron trapping (see text).

FIG. 13. Schematic diagram of functional group electron trapping efficiency on various bilayer dielectric layers.

### DETAILED DESCRIPTION OF CERTAIN EMBODIMENTS

To illustrate certain embodiments and aspect of this invention, six organic semiconductors were grown on four different SiO₂-polymer bilayer dielectric structures and compared to HMDS-functionalized and pristine SiO₂ dielectrics. The results obtained support bilayer dielectric strategy as a general approach to enhancing charge carrier mobility. There is a correlation between semiconductor-polymer combination and OTFT performance, and the nature of the dielectric surface chemical factors underlying such interfacial effects on charge transport. Accordingly, OTFT mobility for certain semiconductors can be modulated to very large extent (several orders of magnitude).

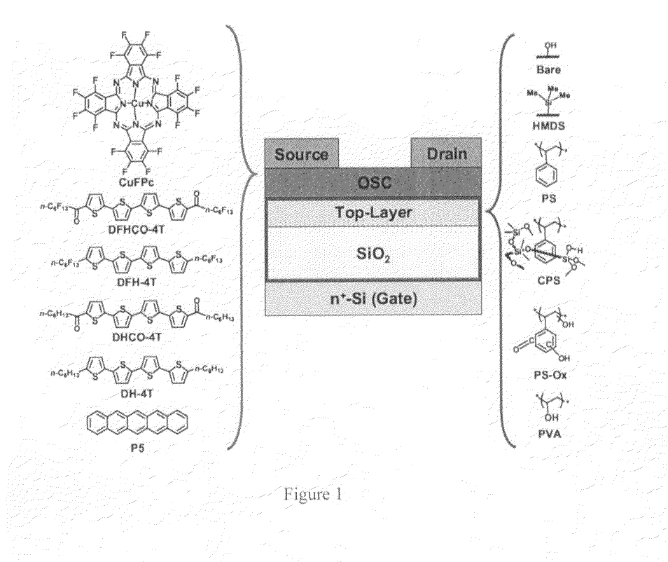

OSCs with very different core structures, chemical functionalities, and frontier molecular orbital (FMO) energies, including those exhibiting hole-, electron-, and ambipolar transport on pristine/HMDS-treated SiO₂ were selected for TFT fabrication (FIG. 1). As a bottom layer of the bilayer dielectrics investigated, is 300 nm-thick SiO₂ thermally grown on p⁺-doped Si was selected because of the ready accessibility of these substrates and the excellent insulating properties with extremely low leakage currents. Indeed, it has been reported that in addition to dielectric surface roughness and dielectric constant, the leakage current through the gate insulator has major consequences for OTFT function. In this regard, a bilayer approach with SiO₂ should enable comparisons of the effects of various polymer surface functionalizations without complications of differing gate leakage currents through the different polymer dielectric layers. Furthermore, with this approach, transistor performance parameters on different dielectric modifications can be realistically compared over the same range of gate voltage/electric fields and charge densities accumulated at the semiconductor-dielectric interface since the relatively thin polymer film can be employed on top of the SiO₂ and therefore maintain the total insulating layer thickness in a similar range. Note that polymeric dielectric materials typically require very different film thicknesses (sometimes very thick) to minimize gate leakage, and that it is not rare to observe mobility variations with the gate voltage/electric field associated with these thickness variations. For purposes of comparison, the top polymer layer can be chosen/modified to provide a wide range of surface/film thickness dimensions and properties, the later including chemical functionality, hydrophilicity, and polymer dielectric constant. All of the new bilayer dielectrics were characterized by impedance spectroscopy, quantitative leakage current density measurements, advancing aqueous contact angles, and atomic force microscopy (AFM). The effects of dielectric surface modifications on the OSC microstructure were investigated in detail using a combination of techniques including AFM, scanning electron microscopy (SEM), and wide-angle x-ray diffraction (WAXRD).

As shown below, polymer coating of inorganic insulators is a general strategy for strongly modulating electron transport in TFT devices, whereas hole transport is much less affected. Experimental results demonstrate correlations between OTFT carrier mobility, relative semiconductor FMO energies, and the chemical nature of the dielectric surface. Insights into the chemical origin of major charge trapping sites are also provided, and it is shown that judicious choice of polymer coatings can “prime” any dielectric surface for organic semiconductor deposition to enhance OTFT performance. Accordingly, this invention can be directed to one or more methods for identifying an optimal dielectric treatment for a particular semiconductor material (e.g., n, ambipolar or p) for an organic field effect transistor. Likewise, without limitation, the present invention can be directed to one or more methods, protocols or procedures for identifying useful dielectric/semiconductor combinations and/or related device structures, meeting one or more pre-determined performance properties. Alternatively, as can be illustrated by various other non-limiting embodiments, this invention can be directed to one or more methods for planarization of one or more such dielectric materials, use of which in combination with a particular semiconductor material can benefit device performance.

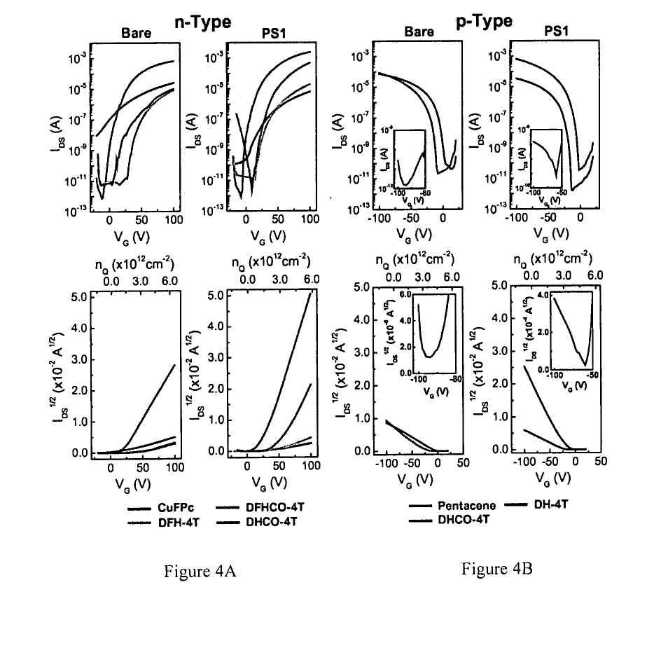

With reference to the following examples and devices fabricated, all OTFT measurements were performed under vacuum (<10⁻⁵ Torr) and the I_{SD}-V_{G} curves analyzed using the standard metal-oxide-semiconductor field-effect transistor (MOSFET) model. For each semiconductor and bilayer batch, at least 10 devices were measured, and no significant (<5%) variations were observed from device to device. FIG. 4 shows typical I_{DS} vs. V_{G} plots for all of the investigated semiconductors on Bare (untreated SiO₂) and PS1 dielectrics. When a number of conditions are satisfied (e.g. V_{DS}≧V_{G}), the channel becomes pinched and the source-drain current enters the saturation regime. The carrier mobility (μₛₐₜ) and threshold voltage (V_{T}) can be calculated from the slope and the horizontal intercept of a linear part in I_{DS, Sat}^{1/2} vs. V_{G} plot, respectively, according to eqs 1 and 2:

$$\begin{matrix}{μ}_{Sat} = {( \frac{\partial \sqrt{{I}_{DS}}}{\partial {V}_{G}} )}^{2} \frac{2 L}{{WC}_{i}} & ( 1 ) \\ {V}_{T , Sat} = {V}_{G} - \sqrt{\frac{2 {I}_{DS} L}{{WC}_{i} μ}} & ( 2 )\end{matrix}$$

where Cᵢ is the capacitance per unit area of the dielectric layer. Turn-on voltage (V_{ON}) is defined as the onset voltage at which I_{DS} begins to increase positively (n-type) or negatively (p-type). To correct for the effects of different dielectric thicknesses and dielectric constants, device carrier mobilities were calculated for the same range of accumulated charge carriers (n_{Q}=Cᵢ·V_{G}/e=4-5×10¹² cm⁻²). The effect of the bilayer dielectric structure on OSC TFT performance is described, below, starting from the n-type semiconductors, followed by the ambipolar and p-type systems. Table 1 collects the OTFT performance parameters such as major carrier type, carrier mobility, threshold voltage, turn-on voltage, and current on-off ratio of all semiconductors studied for different bilayer dielectrics.

The first observation from the data in Table 1 is that all of the semiconductors exhibit the same operational polarity on all dielectrics, as was previously observed for HMDS-treated SiO₂ substrates. Furthermore, we do not observe any of the n/p-type materials to exhibit ambipolar behavior induced by the dielectric, as reported for P5 on PVA. From these data it can be seen that the electron mobility of CuFPc, a well-known air-active n-type semiconductor, is ˜0.01 cm²/Vs, almost insensitive to SiO₂ surface modification. The only exception is for the PVA-based CuFPc devices for which the mobility is about one order of magnitude lower than with the other dielectrics. However, Iₒₙ:I_{off} values change substantially, from ˜10³ on PS-Ox to as high as 10⁶ on HMDS, indicating a variable degree of electron doping (vide infra) typical of this particular material. In contrast, the carrier mobilities of the air-sensitive n-type materials are far more affected by the chemical nature of the dielectric surface.

TABLE 1
OTFT Carrier Mobility (μ, cm²/Vs), Current ON-OFF ratio (Iₒₙ:I_{off}), Threshold Voltage (V_{T}, V) and
Turn-ON Voltage (Vₒₙ, V) for Various Organic Semiconductors on Various Dielectrics.

| | Semiconductors^{a} | | | | | | | | | | | | | |
|---|---|---|---|---|---|---|---|---|---|---|---|---|---|---|
| | n-Type | | | | | | Ambipolar | | | | p-Type | | | |
| | CuFPc | | DFHCO-4T^{b} | | DFH-4T | | DHCO-4T (n) | | DHCO-4T (p) | | DH-4T | | Pentacene | |
| | μ | | μ | | μ | | μ | | μ | | μ | | μ | |
| | (Iₒₙ: | V_{T} | (Iₒₙ: | V_{T} | (Iₒₙ: | V_{T} | (Iₒₙ: | V_{T} | (Iₒₙ: | V_{T} | (Iₒₙ: | V_{T} | (Iₒₙ: | V_{T} |
| Dielectrics | I_{ooff}) | (Vₒₙ) | I_{ooff}) | (Vₒₙ) | I_{ooff}) | (Vₒₙ) | I_{ooff}) | (Vₒₙ) | I_{ooff}) | (Vₒₙ) | I_{ooff}) | (Vₒₙ) | I_{ooff}) | (Vₒₙ) |
| BARE | 0.010 | 17 | 0.44 | 19 | 0.001 | 50 | 0.012 | 50 | 7 × 10⁻⁸ | −50 | 0.022 | −9 | 0.12 | −30 |
| | (10⁴) | (−20) | (10⁸) | (−8) | (10⁶) | (28) | (10⁷) | (5) | (10) | (−61) | (10⁶) | (4) | (10⁷) | (−8) |
| | 0.011 | 36 | 0.38 | 21 | 0.005 | 60 | 0.22 | 42 | 0.002 | −78 | 0.015 | −1 | 0.14 | −23 |
| HMDS | (10⁶) | (4) | (10⁸) | (−6) | (10⁷) | (10) | (10⁷) | (14) | (10³) | (−71) | (10⁶) | (0) | (10⁶) | (0) |
| | 0.007 | 36 | 1.7 | 24 | 0.026 | 48 | 0.70 | 50 | 0.0003 | −60 | 0.024 | −19 | 0.43 | −24 |
| PS1 | (10⁴) | (6) | (10⁹) | (−6) | (10⁶) | (14) | (10⁸) | (12) | (10²) | (−58) | (10⁷) | (−14) | (10⁷) | (−2) |
| | 0.008 | 30 | 1.5 | 25 | 0.024 | 57 | 0.66 | 51 | 0.0004 | −63 | 0.025 | −20 | 0.43 | −24 |
| PS2 | (10⁴) | (4) | (10⁹) | (−4) | (10⁶) | (20) | (10⁷) | (12) | (10²) | (−67) | (10⁷) | (−14) | (10⁷) | (−2) |
| | 0.006 | 42 | 1.5 | 35 | 0.025 | 56 | 0.69 | 53 | 0.0004 | −80 | 0.025 | −18 | 0.43 | −28 |
| PS3 | (10⁴) | (8) | (10⁹) | (0) | (10⁶) | (18) | (10⁶) | (14) | (10²) | (−84) | (10⁷) | (−6) | (10⁷) | (−4) |
| | 0.005 | 48 | 1.4 | 47 | 0.009 | 60 | 0.44 | 61 | 0.0006 | −76 | 0.025 | −18 | 0.40 | −30 |
| PS4 | (10⁴) | (10) | (10⁸) | (0) | (10⁶) | (²⁴) | (10⁶) | (16) | (10²) | (−78) | (10⁷) | (−4) | (10⁷) | (−4) |
| | 0.0006 | 21 | 1.1 | 11 | 0.002 | 37 | 0.11 | 40 | 0.0001 | −79 | 0.017 | −31 | 0.027 | −26 |
| PVA | (10³) | (4) | (10⁸) | (−18) | (10⁶) | (4) | (10⁸) | (9) | (10²) | (−83) | (10⁷) | (−22) | (10⁶) | (−10) |
| | 0.007 | 28 | 1.6 | 22 | 0.004 | 60 | 0.30 | 42 | 0.0002 | −48 | 0.018 | −10 | 0.22 | −17 |
| CPS | (10⁴) | (4) | (10⁹) | (−10) | (10⁶) | (20) | (10⁷) | (10) | (10²) | (−28) | (10⁷) | (−2) | (10⁷) | (−4) |
| | 0.006 | 31 | 0.067 | 23 | 0.0002 | 39 | | | 0.0002 | −68 | 0.016 | −14 | 0.24 | −24 |
| PS-Ox | (10³) | (−36) | (10⁸) | (−8) | (106) | (32) | NA | NA | (10²) | (−40) | (10⁵) | (6) | (10⁵) | (14) |

^{a}The dielectric(gate) substrates were maintained at 50° C. during semiconductor film growth.
^{b}Deposited at room temperature.
^{c}NA means not active.

The OTFT performance parameters of partially air-stable DFHCO-4T on Bare are similar to those on HMDS substrates with carrier mobilities of ˜0.4 cm²/Vs and Iₒₙ:I_{off} of ˜10⁸. However, DFHCO-4T device parameters on the PS-modified SiO₂ and CPS dielectrics are significantly greater with the OTFT carrier mobility approaching 2 cm²/Vs. Interestingly, the off-currents are barely affected by the PS modification, resulting in a slightly increased current on-off ratio from 10⁸ (Bare) to >10⁹ (PSn). These n-type mobilities and current on-off ratios are believed comparable to the largest values reported to date for room temperature OSC film growth and without mobility corrections for electrode contact resistance. Compared to the PS1-based devices, significant diminution of transport characteristics is observed for PVA-based DFHCO-4T devices (μ˜1 cm²/Vs; Iₒₙ:I_{off} of ˜10⁸) and an even greater reduction is measured for PS-Ox devices (μ˜0.07 cm²/Vs; Iₒₙ:I_{off} of ˜10⁸). Similar μ and Iₒₙ:I_{off} trends are observed when DFHCO-4T films are deposited at 50° C. (not shown in Table 2) although overall mobility values are lower by a factor of 2-3. Furthermore, similarly enhanced TFT performance is observed for devices fabricated with thicker PS coatings (PS2-4), demonstrating that the semiconductor-dielectric interface nature governs the carrier transport characteristics which are negligibly affected by the polymer coating layer thickness. This observation has significant implications for practical applications where it may be useful to planarize relatively rough dielectric surfaces with polymer coatings. In contrast, more air-sensitive DFH-4T, an n-type semiconductor active only in vacuum or inert atmosphere, exhibits the greatest sensitivity to the dielectric surface chemistry of the n-type semiconductors examined. Thus, the electron mobility of DFH-4T devices markedly increases from 0.001-0.002 cm²/Vs on Bare and PVA, to 0.004-0.005 cm²/Vs on HMDS and CPS, to 0.02-0.03 cm²/Vs on PSn. As observed for the other semiconductors, DFH-4T devices fabricated with PS-Ox exhibit far lower mobilities (˜10⁻⁴ cm²/Vs). Note that all of the devices exhibit comparable off-currents ˜10⁻¹¹ A) and relatively high Iₒₙ:I_{off} ratios of ˜10⁶-10⁷.

Bilayer dielectric-mediated charge transport variations are even more pronounced for organic transistors fabricated with DHCO-4T, which is one of the highest mobility ambipolar semiconductors discovered to date. We reported previously that optimized DHCO-4T-based TFTs on HMDS exhibit both p- and n-type transport with carrier mobilities of 0.22 and 0.002 cm²/Vs, respectively. Device n-channel operation performance varies dramatically from as low as being negligible on PS-Ox and poor on Bare (μ0.01 cm²/Vs; Iₒₙ:I_{off} of ˜10⁷) to excellent on PSn substrates (μ˜0.4-0.7 cm²/Vs; Iₒₙ:I_{off} of ˜10⁶-10⁸), the latter values approaching those of the best DFHCO-4T-based OTFTs. Similarly to DFHCO-4T and DFH-4T-based TFTs, the electron mobility of DHCO-4T increases on proceeding from PVA (0.11 cm²/Vs) to CPS (0.30 cm²/Vs) substrates, while Iₒₙ:I_{off} remains in the same range (˜10⁷-10⁸). Particularly interesting is the effect of the bilayer dielectric structure on the p-channel operation of DHCO-4T devices. For this borderline p-type material, TFT hole mobilities vary from as low as ˜10⁻⁷ cm²/Vs on Bare to ˜0.002 cm²/Vs on HMDS, whereas for the remaining bilayer dielectric structures, the values fall in the relatively narrow range (0.001-0.006 cm²/Vs), regardless of the nature of the polymer modification. Note that in contrast to n-channel operation, PS-Ox has no detrimental effect on DHCO-4T p-channel transport.

As far as p-type semiconductors are concerned, it is observed in the present work that the performance of DH-4T-based TFT devices can be invariant to the nature of the dielectric, whereas P5 devices exhibit moderate variations of a magnitude in agreement with literature observations (vide infra). Thus, for all dielectric-DH-4T TFT combinations, the hole mobility is ˜0.02 cm²/Vs with Iₒₙ:I_{off}˜10⁷. Pentacene devices on the same range of dielectrics respond in a slightly different manner than the DH-4T devices, with the carrier mobilities increasing from ˜0.1 cm²/Vs (Bare and HMDS) to ˜0.2 cm²/Vs (CPS and PS-Oxy) to ˜0.4 cm²/Vs on PSn. Remarkably, but fully understandably (vide infra), far lower mobilities are measured for PVA-based devices (˜0.03 cm²/Vs). The Iₒₙ:I_{off} ratios of the P5 devices vary from ˜10⁵ (PS-Oxy) to as high as 10⁸ (PS1). Based on the TFT response characteristics of DH-4T and P5 on the bi-layer dielectrics, the effects of the dielectric surface modification on hole-transport properties using various polymeric films or HMDS are seen to be far less dramatic than the effects of the same range of modifications on ‘air-sensitive’ electron-transporting TFT properties.

Another informative semiconductor-dielectric aspect illuminated by this study is the influence of the surface dielectric functionalization on the hysteresis of the I_{DS}−V_{G} transfer characteristics, meaning the degree to which the I_{DS} current depends on the direction of gate voltage sweep. Although OTFT current-voltage hysteresis has potential applications in nonvolatile memory elements, this phenomenon is detrimental to typical OTFT functions. I_{DS}−V_{G} hysteresis has been ascribed to charge trapping in deep states and/or to dipole physical rearrangement/mobile ion accumulation at the dielectric-semiconductor interface. The exact nature and chemical origin of these charged states has not been identified, especially in the case of polymeric insulators.

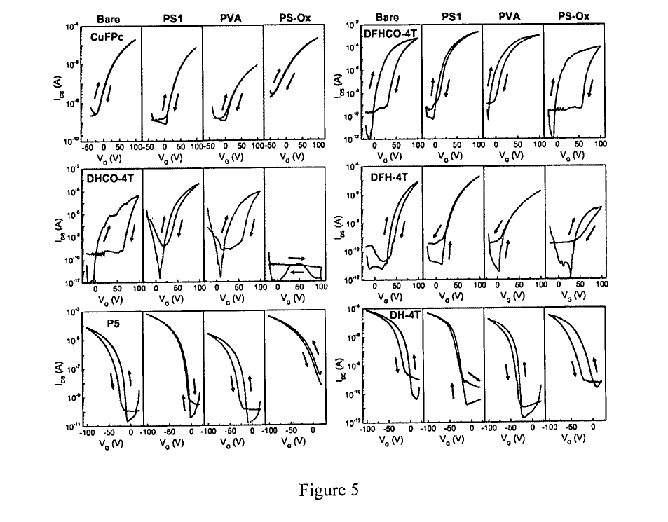

FIG. 5 shows representative transfer plots for both forward and reverse gate bias scans which demonstrate how surface SiO₂ modification affects I_{DS}−V_{G} hysteresis. As a measure of hysteresis magnitude, we introduce the maximum gate voltage shift (ΔV_{G}=V_{G}^{R}−V_{G}^{F}) at a given I_{DS}. The hysteresis data are collected in Table 2. From these data there are several informative trends to note. First, ΔV_{G} invariably exhibits the same sign, independent of the semiconductor-dielectric combination. Second, the extent of the ΔV_{G} change from that for the Bare-based TFTs is similar for all semiconductors, independent of the operation polarity, except for the CuFPc OTFTs. Third, greatest ΔV_{G} variations are observed when comparing PS1 versus PS-Ox devices, with the former exhibiting the smallest variations. Among the n-type semiconductors, the CuFPc-based devices exhibit the lowest hysteresis with a maximum ΔV_{G}=4-5 V on PVA and PS-Ox. Much larger I_{DS}−V_{G} hystereses are observed for n-type DFHCO-4T and DFH-4T and ambipolar DHCO-4T (n-channel operation) especially on PS-Ox (ΔV_{G}=22-60 V), Bare (ΔV_{G}=13-60 V), and HMDS (ΔV_{G}=28-30 V). Typical hystereses for p-type semiconductors P5 and DH-4T are generally lower than those observed for the air-sensitive n-type materials. The largest values for p-type semiconductors are measured for the Bare and PVA substrates (ΔV_{G}=12-18 V) whereas hysteresis is strongly suppressed on PS1 and HMDS (ΔV_{G}=3-6 V). Substantial ΔV_{G} values are also observed for DH-4T on CPS and PS-Ox (ΔV_{G}=10 and 15 V, respectively).

TABLE 2
Hysteresis (ΔV_{G}, V) and Subthreshold Voltage Swing (S, V/dec) Data
for the Semiconductor-Dielectric Combinations Employed in this Study.

| | Semiconductor | | | | | | | | | | | |
|---|---|---|---|---|---|---|---|---|---|---|---|---|
| | n-Type | | | | | | Ambipolar | | p-Type | | | |
| | CuFPc | | DFHCO-4T | | DFH-4T | | DHCO-4T^{b} | | Pentacene | | DH-4T | |
| Dielectric | ΔV_{G} | S | ΔV_{G} | S | ΔV_{G} | S | ΔV_{G} | S | ΔV_{G} | S | ΔV_{G} | S |
| Bare | 2 | 16.7 | 30 | 3.7 | 13 | 3.4 | 60 | 6.3 | 15 | 2.6 | 17 | 2.8 |
| HMDS | 2 | 9.1 | 28 | 3.2 | 30 | 3.2 | 25 | 1.8 | 3 | 2.0 | 6 | 2.4 |
| PS1 | 1 | 5.6 | 7 | 1.5 | 2 | 1.7 | 12 | 1.6 | 3 | 1.6 | 5 | 2.0 |
| PVA | 5 | 10.9 | 15 | 2.9 | 2 | 4.3 | 38 | 2.8 | 18 | 2.3 | 12 | 2.7 |
| CPS | 2 | 5.6 | 14 | 1.3 | 12 | 3.8 | 30 | 2.9 | 5 | 1.2 | 10 | 2.7 |
| PS-Ox | 4 | 50.0 | 60 | 4.0 | 22 | 10.0 | NA | NA | 5 | 10.3 | 15 | 9.1 |

^{a}The hysteresis (ΔV_{G}) estimated by maximum gate voltage shift between the forward and backward sweep at a given I_{DS} (V_{DS} = 100 V) in I_{DS} vs. V_{G} plot.

Microstructural information is useful for understanding the origins of the observed dielectric-dependent TFT response variations. To address these issues, it should first be determined if the largest mobility variations, primarily observed for the air-sensitive n-type materials, are due to differences in charge trapping within the semiconductor film or at the semiconductor-dielectric interfaces having different chemical properties, or to a combination of both. The former should be largely governed by both: i) intrinsic semiconductor molecular/film properties (FMO spatial and energetic characteristics, impurities, level of bulk molecular self-organization) which can reasonably be considered to be constant within the dielectric series, since the semiconductor films were grown simultaneously in the same batch and ii) the dielectric surface which should strongly influence the semiconductor film growth morphology (monolayer/bulk molecular ordering, crystallinity, density of nucleation sites and grain boundaries, molecular alignment). To a first approximation, the latter effects should be dominated by the dielectric characteristics and the processing history/conditions of the dielectric top surface, hence by bulk/interface chemical functionalities. Furthermore, in addition to TFT performance changes, for most of the oligothiophenes investigated here, the interesting question arises as to whether the film growth process is similar to that observed for widely studied pentacene, where different substrate-dependent nucleation kinetics induce dramatic variations in film morphology and microstructure.

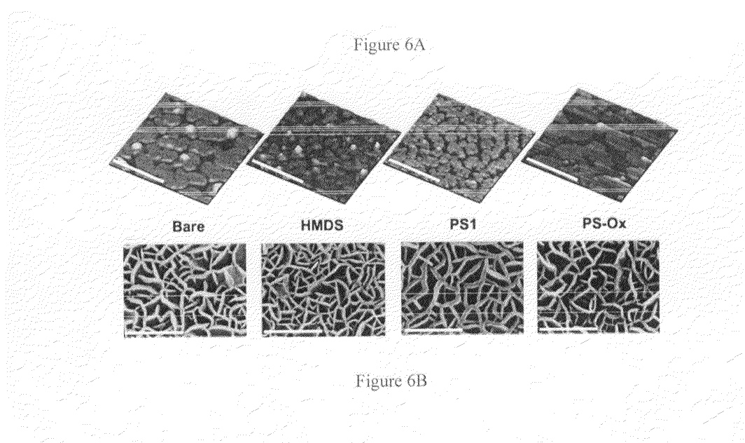

The ambipolar semiconductor DHCO-4T exhibits the greatest substrate/dielectric-dependent electron mobility variations among the semiconductors investigated. FIG. 6 shows AFM and SEM images on four dielectrics for very thin (˜2.0 nm nominal thickness, ˜0.5 ML, ML=monolayer) and thick (˜50 nm) vapor-deposited DHCO-4T films. The great similarity between the SEM pictures raises the possibility that thick film morphologies may not provide significant information on film growth mechanisms nor accurately represent DHCO-4T film morphologies in intimate contact with the dielectric surface. In contrast, the AFM images reveal that for strongly hydrophilic, high surface energy dielectric surfaces such as Bare and PS-Ox, large DHCO-4T grains (>0.5 μm²) form on the dielectric surface, whereas for more hydrophobic substrates such as PS1 and HMDS, crystallites with substantially reduced dimensions form (0.1-0.2 μm²). For some of the other semiconductors, even greater thin film morphological variations with dielectric are observed (vide infra).

These results strongly suggest that different semiconductor film growth mechanisms are involved on different dielectric surfaces, which can be associated with formal Stranski-Krastanov and Volmen-Weber modes. Smith, D. L. Thin-Film Deposition, Principles and Practice, McGraw Hill: New York, 1995, Ch5. The former mechanism is invoked when molecule-molecule interactions are weaker than molecule-substrate interactions, whereas in the latter, molecule-molecule interactions dominate. Note that a film growth characteristic of many oligothiophenes is the tendency to form large (single) crystal plates extending along a crystallographic plane more or less orthogonal to the molecular long axes. This molecular arrangement maximizes core π-π stacking, which represents the dominant cohesive force in these molecular solids. Thus, the combination of these factors governs semiconductor film nucleation and evolution. Without limitation to any one theory or mode of operation, in the initial film growth stage, DHCO-4T molecules impinging upon the Bare and PS-Ox substrates form nanoscopic nucleation sites that, due to the poor affinity of the hydrocarbon chains for the strongly hydrophilic surface, migrate and eventually coalesce laterally to form large grains. In contrast, in the case of hydrocarbon-functionalized PS1 and HMDS dielectrics, every DHCO-4T nucleation site is sufficiently stabilized by the hydrophobic interaction with the dielectric surface to grow and form a large number of small crystallites. However, as argued by the SEM images, the DHCO-4T bulk film microstructures are practically identical for all substrates. To understand the origin of this result and the correlation between charge transport in OTFT semiconducting layers and morphological differences near the semiconductor-dielectric interface, DHCO-4T film growth on the various bilayer dielectric layers was sequentially monitored from ˜0.5 ML to ˜2 ML by AFM.

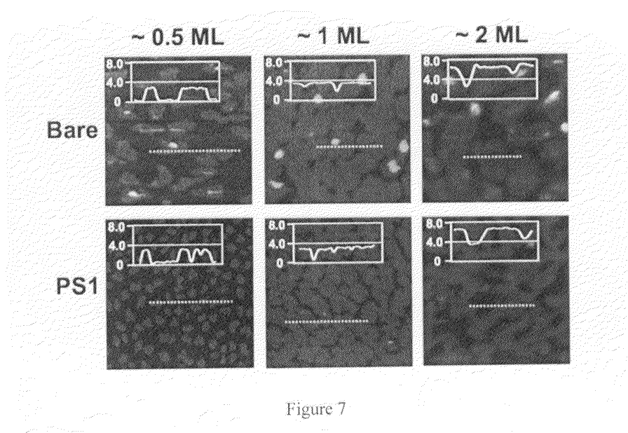

FIG. 7 (left) shows AFM images of ˜0.5 ML DHCO-4T films on Bare (large grains) and PS1 (small grains). With increasing film thickness, both small and large grains on Bare and PS1 samples, respectively, eventually coalesce to form generally uniform first and second layers before the onset of bulk film growth. Interestingly, despite the presence of the perfluoroalkyl chains, a very similar growth process is observed for DFHCO-4T as for DHCO-4T. These growth mode data are further supported by WAXRD experiments (vide infra). Therefore, it is believed that the principal differences in DHCO-4T and DFHCO-4T TFT performance on the different dielectrics is not dominated by different film growth modes or interfacial morphological variations on the dielectric surface since all the dielectrics afford very similar semiconductorfilm microstructures for thicknesses >6 nm (˜2 ML) of interest for TFT transport.

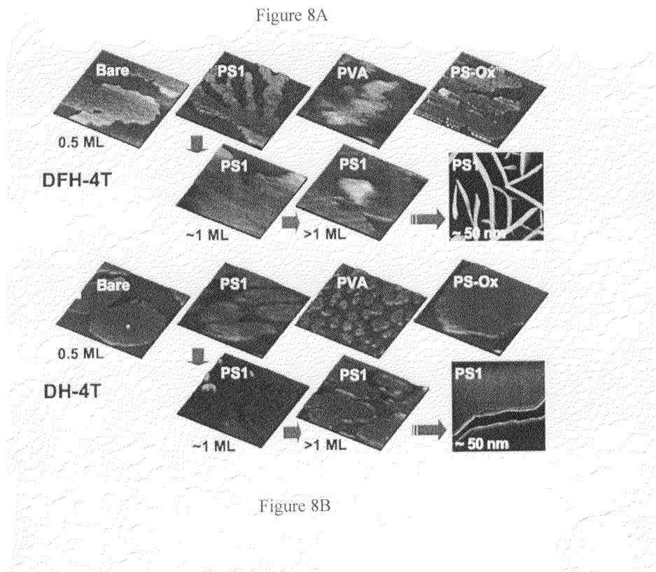

Particularly instructive is the comparison of the first few layers of growth/morphology for perfluorohexyl-substituted quaterthiophene (DFH-4T) versus the corresponding alkyl-substituted quaterthiophene (DH-4T), as shown in FIG. 8. The former material is an n-type semiconductor and its TFT performance is strongly affected by the dielectric surface modifications, whereas the latter is a p-type semiconductor and its TFT performance is essentially invariant to the dielectric surface modification. The bulk mophologies of DFH-4T and DH-4T are quite different (see SEM images in FIG. 8). The former is characterized by well-interconnected elongated grains, while the latter exhibits very large crystallites separated by deep channels. For each semiconductor, similar morphologies are observed for the thick films on the remaining dielectrics (not shown). It is anticipated that the fluorocarbon chains of DFH-4T will have poor affinity for both hydrophilic and hydrocarbon-functionalized surfaces. Therefore, submonolayer DFH-4T films on all dielectrics are characterized by very large two-dimensional plates spanning several microns. Interestingly, the largest and most continuous sub-monolayer grains (>1 μm²) are formed on very hydrophilic Bare and PS-Ox substrates, where the corresponding DFH-4T TFTs exhibit the lowest carrier mobilities. However, in contrast to the previous semiconductors and DH-4T (vide infra), the DFH-4T submonolayer to multilayer transition (shown in FIG. 8A for PS1) occurs before the first layer is completely filled. Note that a very similar film growth pattern is observed on all the other dielectrics, demonstrating again that the large electrical parameter variations in DFH-4T OTFTs are not due simply to different semiconductor film morphologies.

From a completely different perspective, the same conclusions can be drawn when analyzing DH-4T film growth. Note that it has been reported previously that ultrathin DH-4T films tend to grow 2-dimensionally on SiO₂ with very uniform and large grains, and that the first two monolayers of this particular semiconducting material dominate field-effect mobility in the bottom-contact TFT configuration. In contrast to DFH-4T, very large differences in the initial film growth pattern are observed for DH-4T, the details of which depend on the particular bilayer structure (see FIG. 8B). However, all films on the different bilayer structures exhibit similar morphological transitions from sub-monolayer to bilayer to bulk film (shown in FIG. 8—bottom for PS1). Note that the dielectric surface dependent differences between the initial film growth mechanisms (up to ˜2 ML) are the greatest for DH-4T among the oligothiophenes investigated. However, note that the hole mobility for DH-4T is completely unaffected, again arguing for predominant molecular control of the OTFT parameters for this particular semiconductor (vide infra).

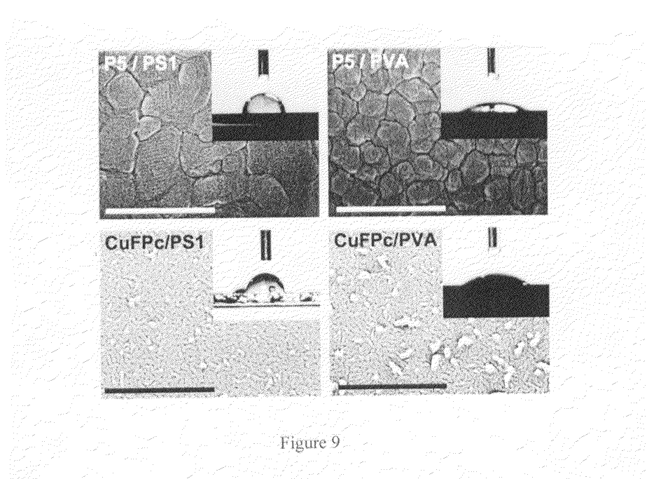

Some aspects of the influence of dielectric surface functionalization, as well as other film deposition parameters, on the morphology of pentacene and CuFPc films were recently reported. For these systems, we find morphological variations in the present study that are similar to the previous reports with some informative exceptions. Typically, when submonolayer P5 films exhibit a large (small) number of nucleation sites, this invariably gives rise to the formation of small (large) grains for the bulk films with more (less) grain boundaries. FIG. 9A shows SEM images for 50 nm thick P5 films deposited on PS1 and PVA, which indicate that this material exhibits the greatest dielectric surface-induced bulk morphological changes within the present semiconductor series. Although all thick P5 films exhibit the formation of typical terraced features, the grain size on HMDS (not shown) and on PS1 substrates is much larger (˜7× and 5×, respectively) than observed on PVA. A plausible explanation for the large grains on PS is the affinity of pentacene for an acene-functionalized surface such as polystyrene. A similar phenomenon has been reported for pentacene TFTs fabricated on a phenyl-containing monolayer gate dielectric for which good pentacene self-organization and mobility were measured. N-channel CuFPc films grown at relatively low temperature (<100° C.) are invariably characterized by very small crystallites. Similar results are observed here for CuFPc films deposited on the other bilayer dielectrics. The greatest crystallite size variations, still relatively small compared to P5 films, are seen again when comparing HMDS (not shown) and PS1 dielectrics/substrates to PVA. CuFPc films on the latter dielectric exhibit the formation of a large number of flakes with 2-3× smaller grain size (FIG. 9B—right).

Equally substantial evidence for dramatically different P5 and CuFPc film morphologies on PVA compared to those on PS1 is revealed by advancing aqueous contact angle measurements on surfaces of the semiconductor films. As shown in FIG. 9, the wettability of P5 films is very different on going from PS1 (as well as the other dielectrics) to PVA substrates, since θ changes from ˜85° for ˜20°. CuFPc behaves similarly, with θ being 95° for all dielectrics with the exception of PVA (˜25°). Furthermore, θ decreases even more with time and eventually the water drops spread completely and delaminate the semiconductor films. This is a clear demonstration that water can easily penetrate between the P5 or CuFPc grains and dissolve the PVA coating beneath. Hence, the channels between grains are deep and reach the PVA surface. Note that this is not a peculiarity of all the PVA/semiconductor structures (PVA is water-soluble) since in case of the semiconductor films other than pentacene and CuFPc, the contact angle is essentially independent of the underlying dielectric layer and time and is found to be: DH-4T (˜90°), DHCO-4T (˜100°), DFH-4T (˜110°), DFHCO-4T (˜130°). Since water cannot reach the dielectric surface, this is clear evidence that for all of the present oligothiophene semiconductors, all bilayer dielectric surfaces are covered by (at least) a completely filled molecular layer.

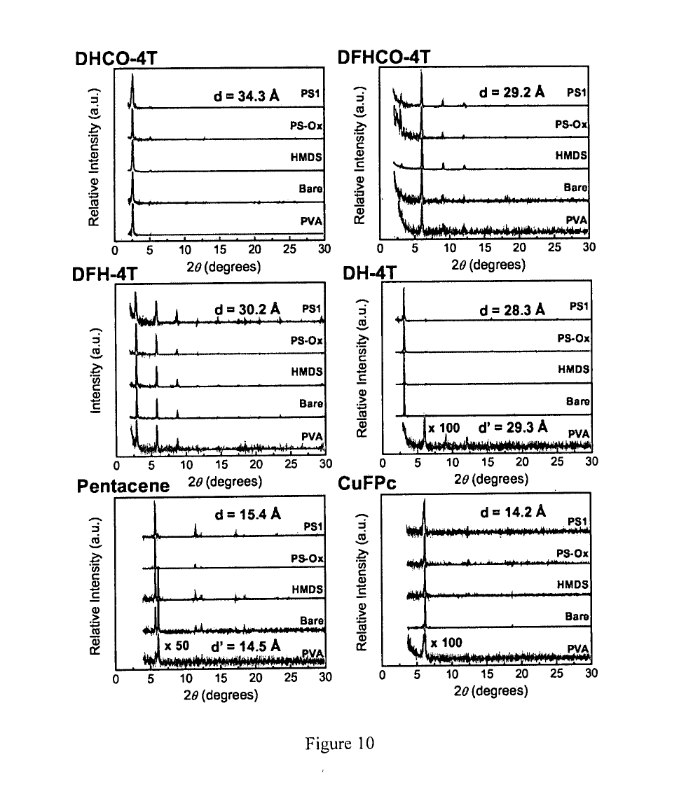

To further investigate film semiconductor microstructure and degrees of texture, WAXRD measurements were performed for all semiconductor-dielectric combinations. FIG. 10 shows θ-2θ scans and the corresponding d-spacings. With the exception of pentacene, all of the organic semiconductor films on the different dielectrics exhibit a single progression of equally spaced Bragg reflections. The d-spacing patterns of the ambipolar/n-type materials [DHCO-4T (34.3 Å), DFHCO-4T (29.2 Å), DFH-4T (30.2 Å), and CuFPc (14.2 Å)] are completely insensitive to the dielectric functionalization and are identical to the values observed for HMDS-treated SiO₂ substrates. For all semiconducting films in the present study, a general trend has been observed in the maximum intensities of each semiconductor film (of identical thickness) WAXRD scan on the various bilayer dielectrics falls in the order of PS-Ox>Bare˜HMDS>PS˜PVA. Importantly, the highest and lowest degrees of texture in air-sensitive n-type semiconductor films on PS-Ox and PS/PVA, respectively, are not directly correlated with the apparent device performance trends (Table 1, μ_{PVA}>>μ_{PS-Ox}). Considering that for the air-sensitive n-type semiconductors, each type of semiconductor film on the various bilayer structures is prepared in a single batch leading to the same film thickness, and that the maximum θ-2θ scan intensity variation on different bilayer structures is relatively small (within a factor of 2-5), this provides additional evidence that their transistor performance variation can be ascribed to differences in semiconductor-dielectric interface chemical properties rather than to the film morphology/microstructures (vide infra). In contrast, the intensity of the WAXRD scans of the air-stable n-type and p-type semiconductors on PVA is significantly lower by a factor of 50-100 than those on the other dielectrics as indicated in FIG. 10, while the overall maximum intensity variation on various bilayer dielectrics follows the trend PS-Ox>Bare≦HMDS>PS>>PVA. Especially, in the case of CuFPC on PVA, the first-order diffraction peak exhibits not only substantially less intensity but also a twice larger full-width-at-half-maximum (FWHM ˜0.4° in 2θ) than the same semiconductor films on the other bilayer dielectrics, indicating a poorly ordered film microstructure on PVA. The poor crystallinity of CuFPC, DH-4T, and P5 films on PVA as revealed by WAXRD can be correlated with relatively poor performance of the corresponding TFT devices (Table 1).

In addition to the relatively low degrees of film texturing, DH-4T and P5 films on PVA exhibit different molecular orientations from those observed on the other dielectric surfaces. DH-4T WAXRD scans exhibit a single set of reflections, however, the d-spacing calculated for films grown on PVA (29.3 Å) is significantly larger than that found on all of the other substrates (28.3 Å), demonstrating a different growth mode. WAXRD θ-2θ scans of the P5 films reveal an interesting dielectric-promoted microstructural transition. Briefly, P5 films on PS1 and PS-Ox are characterized by an almost phase-pure film, with a d-spacing of 15.4 Å, whereas on PVA evidence of a different single phase is observed with d=14.5 Å, and these two d-spacings correspond to the so-called, previously identified ‘thin film’ and ‘bulk’ pentacene phases, respectively. Note that the WAXRD scans of P5 films on HMDS and Bare exhibit the presence of both phases with comparable diffraction intensities. To a greater extent, the films of the p-type materials on PVA are characterized by Bragg progressions with far smaller intensities and broader widths than those of the same thickness grown on the other substrates, indicating that both P5 and DH-4T on PVA exhibit less ordered film microstructures.

To summarize these observations, the morphology and microstructure within the air-sensitive n-/ambipolar semiconductors are insensitive to the dielectric layer surface whereas the TFT charge transport is extremely sensitive. In contrast, the air stable n-type and p-type materials exhibit relatively modest dielectric-related TFT performance alterations despite the much greater variations in semiconductor film morphology, crystallinity, and molecular orientation.

Such results for OTFTs fabricated on bilayer dielectrics having diverse surface chemical functionalities and using a broad range of organic semiconductor types provide new insights into critical relationships between OTFT performance parameters and semiconductor molecular/electronic structure, semiconductor film microstructure evolution, growth mechanism, and dielectric surface characteristics. Although it is not always possible to unambiguously differentiate among the relative contributions of all of these interconnected effects, the investigation underlying this invention provides clear evidence as to which of the aforementioned effects dominates for devices fabricated with most semiconductor-dielectric combinations.

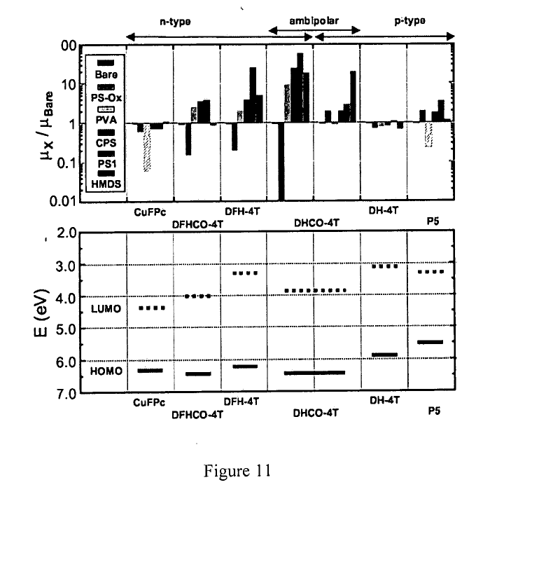

Since unfunctionalized SiO₂ is the substrate from which all of the functionalized/bilayer dielectrics are fabricated, this insulator can be a reference point to better understand the origins of performance variations. In the case of carrier mobility, to clearly visualize changes, an enhancement factor η=μₓ/μ_{Bare} is defined as the ratio of the field-effect carrier mobility observed for a certain bilayer structure X(μₓ) and that measured on the Bare (μ_{Bare}) substrate. These results are plotted in FIG. 11A for all of the semiconductors investigated. It can be clearly seen that η increases on average when moving from the sides to the center of the plot, hence from the less air-insensitive n-type and p-type semiconductors to the more sensitive n-type and ambipolar materials. Therefore, there is a distinct correlation between the dielectric surface chemistry and the empirical sensitivity of the semiconductor majority carrier type to ambient. FIG. 11B plots the electrochemically-derived frontier molecular orbital energy levels (HOMO and LUMO) for the semiconductors employed in this study. Note that the low-lying LUMO and high-lying HOMO molecules are generally those exhibiting the least sensitivity to the nature of the dielectric surface. Consequently, the utility of employing OSCs having progressive variations in MO energies to probe semiconductor-dielectric interfacial properties finds experimental confirmation.

The general trend in OTFT mobilities as a function of the various bilayer dielectrics can be summarized by the following observations: 1) For air-stable n-type semiconductors such CuFPC as well as cyanated perylene derivatives, OTFT performance parameters are relatively insensitive to the dielectric surface (0.7<η_{CuFPc}<1.1), with the reasonable exception of PVA (vide infra). 2) The n-type mobilities and current on-off ratios of air-sensitive n-type semiconductors such as DFHCO-4T, DFH-4T, and ambipolar DHCO-4T vary substantially (0<η_{n-type}<100) with the nature of dielectric surface, and the performance enhancement is most pronounced in the n-type mobility of DHCO-4T films on PSn dielectrics. 3) The effects of bilayer dielectrics on the p-type semiconducting properties of DH-4T and P5 are minimal (0.8<η_{p-type}<1.3, with the exception of PVA-P5 where η_{P5}=0.2) even on PSn and PS-Ox, which induce dramatic mobility increases and decreases, respectively, in the air-sensitive n-type devices.

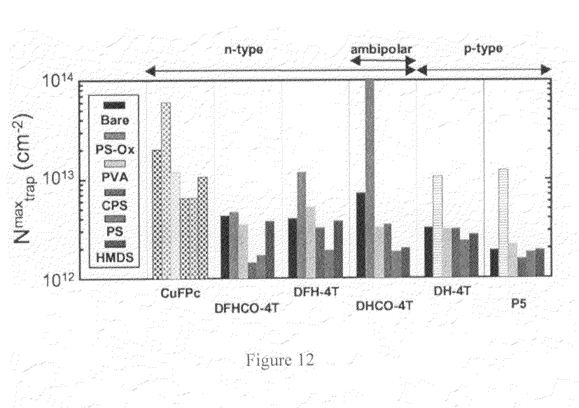

Considering that each semiconductor is simultaneously grown on the various bilayer dielectric layers in a single batch and that great similarities have been demonstrated in semiconductor film morphologies and microstructures, it is reasonable that the observed performance differences for each semiconductor set can be largely attributed to differences in the details of the dielectric-semiconductor interface chemistry. As shown from variable-temperature mobility studies on n-channel organic transistors, the charge transport in these materials is largely limited by poorly understood charge traps, in contrast to the coherent bandlike transport operative in most inorganic semiconductors. These traps are thought to be localized at chemical/physical defects, at semiconductor grain boundaries, and/or at the semiconductor-dielectric interface. Trap density changes can be estimated by relative V_{T} shifts with respect to that in reference samples (Δnₜᵣₐₚ=(CᵢΔV_{T})/q), where q is the charge on an electron, or by the difference between V_{T} and Vₒₙ in the same device (nₜᵣₐₚ=[Cᵢ(V_{T}−Vₒₙ]/q). Note that V_{T} is a fitting parameter derived from (I_{DS})^{1/2} vs. V_{G} plots and can vary substantially, depending on the applied gate bias, especially when OTFT devices exhibit gate-bias dependent mobility, gate stress effects, and/or hysteresis. In contrast, the subthreshold swing (S) should be less dependent on the aforementioned artifacts. Regarding the electrical properties of dielectric-semiconductor interfaces in TFT devices having different dielectric structures, the maximum density of traps can be estimated from eq. 3:

$${N}_{trap}^{max} = \frac{{C}_{i}}{q} [ \frac{qS log e}{kT} - 1 ] \qquad ( 3 )$$

where k is Boltzmann's constant, T is temperature, e is the base of the natural logarithm, and Cᵢ is the areal capacitance of the dielectric structure. (See, a: Unni, K. N. N.; Dabos-Seignon, S.; Nunzi, J.-M. J. Mater. Sci. 2006, 41, 317; and b: Rolland, A.; Richard, J.; Kleider, J.-P.; Mencaraglia, D. J. Electrochem. Soc. 1993, 140, 3679.) McDowell, M.; Hill, I. G.; McDermott, J. E.; Bernasek, S. L.; Schwartz, J. Appl. Phys. Lett. 2006, 88, 073505/1.) The estimated trap densities for the various semiconductor dielectric pairs are depicted in FIG. 12. When bulk trap densities in the semiconductor layer are similar among different dielectrics or are far less than interface trap densities, the trend in trap density estimated from eq. 3 can be ascribed mainly to trapped charges at the semiconductor-dielectric interface and used as the maximum estimated interface trap density. This is a valid assumption for the air-sensitive n-type semiconductors and p-type DH-4T in view of the similarities demonstrated in the semiconductor film properties. Therefore, a recognizable correlation might be expected between the mobility enhancement effects and the estimated trap densities, in turn dependent on the dielectric surface modifications.

Interestingly, it can be seen that similar trap density patterns are observed among the airsensitive n-type semiconductors although trap density comparisons using eq. 3 are formally valid only for transistors having identical semiconductors. The apparent trend is that PS-Ox exhibits the greatest trap densities followed by Bare or PVA, while CPS and PS1 exhibit the lowest densities. In addition, the trend in interface trap density as a function of bilayer dielectric structure exhibits a close correlation with TFT mobility for the n-type semiconductors having high-lying LUMOs. Thus, in the case of DFHCO-4T, DFH-4T, and DHCO-4T, PS1 devices with the highest mobilities exhibit lowest interface trap densities and PS-Ox devices with the lowest mobilities exhibit the largest interface trap densities.

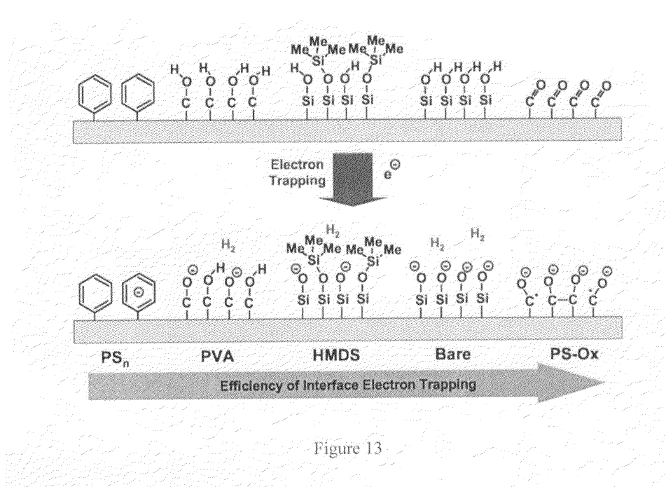

Although the nature of interface traps is doubtless dependent on intricate microstructural details of the interaction between the semiconducting and dielectric layers, the interface trap density can be qualitatively understood from a chemical perspective (FIG. 13). It is known that in the absence of special surface modifications, Bare substrates exhibit an interface trap density of ˜10¹² cm⁻² which is principally attributed to interfacial chemical functionalities/species such as Si—OH in conjunction with adsorbed H₂O, and adventitious carbon contamination. Such chemical defects can affect charge transport by deep-trapping/doping and/or by scattering carriers at the semiconductor-dielectric interface, and this effect is reflected in device performance parameters. Such interfacial effects are important in organic semiconductor-based devices since the charge transport process is believed to occur within the very first few semiconducting layers in proximity to the gate dielectric. Note that the chemical functionalities depicted in FIG. 13 should preferentially trap electrons (rather than holes) leading to mobility suppression in n-type semiconductors, and that for p-type semiconductors, the principal outcome is believed to be introduction of extra holes at the semiconductor-dielectric interface for charge balance and a positive V_{T} shift. The importance of controlling interface traps was demonstrated in the realization of ambipolar pentacene TFTs. It was reported that substantial n-type activity in pentacene TFTs is enabled by compensating electron traps at the semiconductor-dielectric interface via introduction of an ultranthin Ca layer between the pentacene and SiO₂ layers. (See, Ahles, M.; Schmechel, R.; von Seggern, H. Appl. Phys. Lett. 2004, 85, 4499.) More recently, it was reported that n-type activity in known p-type semiconductors (e.g. F8T2) is stabilized by passivating surface electrontrapping silanol groups (Si—OH) on the SiO₂ dielectric and suggested that their electron affinity is 3.9 eV. (See, Chua, L.-L.; Zaumsell, J.; Chang, J.-F.; Ou, E. C.-W.; Ho, P. J.-H.; Sirringhaus, H.; Friend, R. H. Nature 2005, 434, 194.) Note that the LUMO energies of air-sensitive n-type semiconductors DFHCO-4T, DFH-4T, and DHCO-4T lie very close to or above the negative of this value, while that of air-stable n-type CuFPc is far lower (FIG. 11B). Indeed, the mobility enhancement observed on passivating trap-active SiO₂ surfaces using HMDS vs. Bare is significantly more pronounced for semiconductors with higher LUMO energies (DFHCO-4T<DFH-4T, DHCO-4T), while CuFPc exhibits very similar mobility on Bare and HMDS (FIG. 11A), implying that electron-trapping on surface-modified dielectrics is related to the ambient sensitivity/LUMO energies of n-type semiconductors and to the chemical nature of the dielectric surface. Note that although it was previously suggested that elusive n-type organic semiconductor behavior is governed by interface traps, especially on SiO₂, the present analysis is believed to be the first study to explicitly relate dielectric surface chemistry to OTFT performance enhancement via the semiconductor FMO energetics and interface traps.

The very significant interface trap reduction on PSn is supported by several mechanistic arguments: 1) effective passivation of surface chemical defects with a very smooth morphology and minimal nanoscopic pinholes, 2) possible stabilization of charge carriers at the dielectric interface by aromatic cores. Regarding improved device stability and performance, Me₃Si-terminated HMDS-treated dielectric surfaces have been shown to generally enhance OTFT performance. This strategy has been extended to dielectric surface modification using long-chain organosilanes such as octradecyltrichlorosilane (OTS). The origin of the device performance improvement by this organosiloxane interface modification is doubtless the substantial reduction in electron-trapping silanol density on the SiO₂ surface without affecting the dielectric surface morphology/roughness. However, it has been shown that silanol groups cannot be completely removed by such self-assembled alkyl layers and that the relatively thin self-assembled alkyl monolayers (<2 nm) are subject to charge carrier tunneling. Note also that the larger advancing aqueous contact angle on HMDS (102°) versus PSn (92°) does not necessarily mean complete surface coverage. Furthermore, recent x-ray photoelectron spectroscopic studies of HMDS-SiO₂ surface modification demonstrate that even after careful HMDS treatment, adventitious carbon contaminants, including some carbonyl groups, which are efficient electron traps (vide infra), still remain. In contrast, surface modification with electrically ‘inert’ and relative thick PS coatings (>24 nm vs. <1 nm for HMDS) should completely cover the SiO₂ surface, contain minimal pinholes, and more effectively cover/passivate ‘trap-generating’ surface functionalities without significant changes in surface morphology (ρ˜0.3 nm). Note also that the LUMO level of PS, estimated from the electrochemical reduction potential of benzene, is ˜−1.5 eV—too high to act as an electron trap.

Self-assembled monolayers having phenyl or fused-arene termini on SiO₂ dielectric surfaces are claimed to stabilize charge transport in pentacene OTFTs. It was reported that pentacene TFTs on SiO₂ modified with self-assembled monolayers having pendant phenyl groups exhibit low off currents and low subthreshold voltage swings. It was reported that pentacene transistors based on phenyltrichlorosilane-modified dielectrics exhibit good hole mobilities (˜0.7 cm²/Vs) and low off current levels (10⁻¹² A) at zero gate bias, in contrast to devices on self-assembly-modified SiO₂ using phenyl groups with electron-withdrawing, dipolar substituents. More recently, SiO₂ dielectric surface modification with self-assembled anthracene layers has also been reported to reduce charge trapping state densities as well as subthreshold voltage swings. The interaction between arene-modified surfaces and organic semiconducting films is not fully understood, however it can be hypothesized that similar interactions may occur between semiconductor and PS layers, considering the chemical similarities. Although spin-coated PS layers are expected to have more random orientations of phenyl substituents with respect to the surface, this “soft” surface may better conform to semiconductor crystal growth patterns, and the surface coverage should be complete with minimal pinholes, in contrast to self-assembled systems where incomplete coverage or local structural defects may occur.

As shown in FIGS. 11 and 12, PVA-based devices exhibit lower enhancement factors (q) and higher trap densities than PS-based devices. One possible explanation concerns the influence of dielectric constant. Veres et al reposed that amorphous semiconducting polymers exhibit higher performance parameters on polymeric insulators with low dielectric constants than on those with high dielectric constants, and argued that local polarization effects in high dielectric constant polymers may induce the localization of carrier states by dipolar disorder. Such dipolar disorder effects were also proposed in OTFTs using polycrystalline and single-crystalline organic semiconductors. Considering the relatively low dielectric constant of PS (k=2.5) and CPS layers (k=2.6) vs. PVA (k=7.4), it is possible that the reduced carrier localization/trapping at the low k dielectric interface contributes to low interface trap densities and enhanced electron mobilities. In contrast, other results suggest that high k dielectric materials increase mobility. In any case, note that C—OH groups should be differentiated from Si—OH groups in terms of electron trapping. It has been proposed that the electron trapping mechanism on SiO₂ surface involves electron capture by protons and release of H₂, suggesting that the stable negative charges are formed on SiO₂ and that traps are consumed (eqs. 4-6). The acidity of the hydroxyl group plays a key role in shifting the equilibrium toward the right, hence enabling electron trapping.

≡Si—O—S≡+H₂O [symbol] 2SiOH (4)

≡Si—OH+H₂O [symbol] SiO⁻+H₃O⁺ (5)

≡Si—O⁻+H₃O⁺+e⁻ [symbol] SiO⁻+H₂O+½H₂ (6)

Note that a mechanism based on similar reactions are plausible for alcohols. However, alcohols and phenoles (C—OH) are less efficient proton donors (pKₐ˜10-15) and less likely to capture electrons compared to silanols (pKₐ˜5). In fact, as shown in FIG. 11, all n-type semiconductors with high-lying LUMO levels exhibit higher mobilities on PVA than on Bare by a factor of 2-8, arguing that the presence of alcohol (not silanol) functionalities is less detrimental to n-type charge transport, and that the enhanced n-type mobility may be due to the passivation of surface silanol groups as in PSn. Note that n-type transport was previously demonstrated in pentacene and polymer-blend-OTFTs on PVA dielectrics.

Considering that the semiconducting film morphologies and microstructures on PS-Ox are very similar to those on the other bilayer dielectric structures, the very poor OTFT performance observed on PS-Ox, even compared to that on Bare, must be related to the semiconductor-dielectric interface. Despite short exposure times with minimal power (5s, 20W), plasma-induced reactions are expected to generate oxidation-related surface chemical defects, although the gross PS-Ox surface morphology remains smooth (ρ˜0.3 nm) and the capacitance is almost identical to that of PS1 (Table 1). As shown in FIG. 12, a relatively high trap density is estimated on this substrate for all semiconductor combinations (>10¹³ cm²) and can be ascribed to the chemical functionalities generated by the O₂ plasma treatment. Previous studies of O₂ plasma-treated PS surfaces using ATR-FTIR and NEXAFS found that the density of oxidized-carbon functionalities, especially carbonyl groups, is significant. Carbonyl groups should have substantial electron affinities, and based on the electrochemical reduction potentials⁷¹ of acetophenone (−1.99 V), benzophenone (−1.72 V), and methylvinylketone (−1.11 V) versus SCE, the estimated LUMO energies of carbonyl functionalities generated by the O₂ plasma should lie within −2.8-−3.7 eV. This range of LUMO energies is very close to those of the air-sensitive n-type semiconductors, and carbonyl groups on the dielectric surface are therefore expected to strongly perturb electron transport at the semiconductor-dielectric interface by trapping electrons. This effect is most pronounced in case of DHCO-4T on PS-Ox where n-type activity completely disappears. Note also that the estimated trap density on PS-Ox is much greater than on Bare, indicating that the carbonyl groups more efficiently trap electrons than silanol. In case of p-type semiconductors, the effect of electron trapping on device performance is primarily the positive shift of V_{T}, and its extent is far more pronounced on PS-Ox than on Bare as shown in FIG. 5 (vide infra).

In addition to mobility modulation, the current-voltage hysteresis evident in the present transfer plots can be tuned by employing different bilayer dielectrics. Thus, while PVA films are known to act as insulators and exhibit hysteresis which presumably arises from charge storage and polarization, PVA efficacy as a polymeric gate electret has also been demonstrated. In contrast, the more remarkable hysteretic behavior on PS-Ox substrates (FIG. 5) must be related to a very large density of deep interface traps. In the case of n-type semiconductors on PS-Ox, the interface trap states are estimated from the subthreshold swing to be ˜10¹³ cm⁻², much greater than those on the other bilayer structures, and causes serious current-voltage hystereses by binding electrons in these rather deep traps at the semiconductor-dielectric interface. Also, this type of electron trapping is partially indicated by gate-bias dependent semiconductor mobilities in the n-type TFTs on PS-Ox. As argued from the AFM morphology results on the very thin films of these semiconductors, the observed mobility variations are largely governed by dielectric surface chemistry rather than by gross film morphology or growth mechanism, and such semiconductor-dielectric interactions are clearly revealed by the interface trap densities.

From the discussion of surface chemistry-related interface trap energetics, it is arguable that the relative insensitivity of air-stable n-type CuFPc performance to the dielectric surface chemistry can be ascribed to the very low-lying LUMO. In contrast to the air-sensitive n-type semiconductor devices, airstable CuFPc devices do not exhibit direct correlation between the observed semiconductor mobilities and the (overall high) estimated trap density (>10⁻¹³ cm⁻²), although the trap density variation pattern is similar to those of the air-sensitive n-type semiconductors. The reason is likely an overestimated trap density due to charge trapping in the semiconducting layer by chemical impurities. Note that CuFPc exhibits a very low-lying LUMO energy, also indicating that this semiconductor is vulnerable to reversible/irreversible doping by chemical impurities rather than to the aforementioned interface chemical functionalities. Indeed, CuFPc TFTs exhibit relatively high I_{DS} currents at zero gate bias (FIG. 4), and the theoretically estimated charge accumulation density at the semiconductor-dielectric interface at V_{G}=50 V (3×10¹² cm⁻², n=Q/e=(Ci×V_{G})/e) is far lower than the estimated trapped charge density in FIG. 12. Therefore, the estimated trap density includes traps both in the semiconducting layer and at the semiconductor-dielectric interface. Considering that CuFPc films on different dielectrics exhibit different morphologies, the observed mobility modulation in the various bilayer dielectric structures can be attributed to the combined effects of bulk semiconductor film morphology/doping and the semiconductor-dielectric interface.

The estimated trap densities of the present p-type semiconductors except on the PS-Ox substrates, are almost constant, which is opposite to the air-sensitive n-type semiconductor trends (FIG. 12). Since DH-4T exhibits essentially the same film morphology and microstructure on all of the present bilayer dielectrics, the similarity in calculated trap densities can be ascribed to invariant semiconductor-dielectric interfacial properties. Therefore, the nearly constant hole mobilities of DH-4T on the different dielectrics can be correlated with the relative insensitivity of hole transport to the dielectric surface nature. Note that in case of DH-4T on PS-Ox, which exhibits much greater interface trap density than on other dielectric surfaces, V_{T} is shifted positively to 23 V compared to that on Bare (9.0 V). The off current is also significantly increased due to the extra holes created by electrons filling the interface traps, and the relatively large hysteresis can be explained in a similar way. In contrast, the estimated trap densities in pentacene devices do not offer a clear picture of interface trapping. Although similar trends in estimated trap densities are apparent in pentacene devices on the bilayer dielectric structures, differences in film morphologies and microstructures revealed by SEM and XRD indicate that the estimated trap densities are affected by the grain boundaries in the semiconducting layer, molecular orientation, degrees of texture, and the surface chemistry of the semiconductor-dielectric interface. For example, although pentacene TFTs on PVA exhibit relatively low trap densities, which are very similar to those on other bilayer structures except PS-Ox, OTFT performance is poorest even compared to that on PS-Ox which exhibits very high trap densities. As demonstrated by the SEM and advancing aqueous contact angle data, such inferior device performance can be principally attributed to small, discontinuous grains in the semiconducting film. Therefore, unlike the air-sensitive n-type semiconductors and DH-4T, which exhibit relatively similar solid-state film behavior on different bilayer dielectrics, assessment of trap densities here involves changes in semiconductor properties such as grain sizes as well as in the semiconductor-dielectric interface.

As discussed above, the present invention provides a general approach to probe OTFT semiconductor-dielectric structures using tailored bilayer dielectrics. Very different organic semiconductors with p-, n-type, and ambipolar charge transport characteristics are grown on different bilayer dielectric structures and systematically characterized by AFM, SEM, advancing aqueous contact angles, and WAXRD. In concert, the corresponding transistor device response parameters were investigated in detail. For instance, representative of this invention, polystyrene coatings on SiO₂, with minimal gate leakage and surface roughness, significantly enhance the mobilities of air-sensitive n-type semiconductors, while such kinds of device performance improvement is nominal in case of air-stable n-type and p-type semiconductors. Based on interface trap density estimations on the various bilayer structures, electron trapping at the semiconductor-dielectric interface is identified as the origin of the mobility sensitivity to the different surface chemistries in the n-type semiconductor systems having high-lying LUMOs. The present semiconductors exhibit very similar film morphologies and microstructures, regardless of the dielectric surface modification. Such a result demonstrates that controlling dielectric interface chemistry can be used to achieve good n-type performance in OTFT configurations and that the proper choice of n-type semiconductor can be utilized to probe interface properties such as trap types and densities on various dielectric surfaces, without perturbation of the semiconducting film morphology and microstructures on top.

### EXAMPLES OF THE INVENTION

The following non-limiting examples and data illustrate various aspects and features relating to the dielectric semiconductor structures, devices and/or methods of the present invention, including the fabrication of thin film transistor devices, as are available in light of the considerations described herein. In comparison with the prior art, the present structures, devices and/or methods provide results and data which are surprising, unexpected and contrary thereto. While the utility of this invention is illustrated through the use of several components, structural combinations and devices in conjunction therewith, it will be understood by those skilled in the art that comparable results are obtainable with various other components, structural combinations and/or devices, as are commensurate with the scope of this invention.

Materials. The semiconductors α,ω-diperfluorohexylcarbonylquaterthiophene (DFHCO-4T), α,ω)-dihexylcarbonylquaterthiophene (DHCO-4T), α,ω)-diperfluorohexylquaterthiophene (DFH-4T), and α,ω)-dihexylquaterthiophene (DH-4T) are available as described in the literature, while pentacene (P5) and hexadecafluoro-copperphthalocyanine (CuFPc) were purchased from Aldrich and purified by multiple gradient vacuum sublimation before use. Polystyrene (PS, M_{w}=280k) and polyvinylalcohol (PVA, Mowiol 40-88, M_{w}=127k) were purchased from Aldrich and used without further purification. Prime grade silicon wafers (p⁺-Si) with 300 nm (±5%) thermally grown oxide (from Montco Semiconductors) were used as device substrates.

Film Deposition and Characterization. All p⁺-Si/SiO₂ substrates were cleaned by sonication in absolute ethanol for 3 min and by oxygen plasma treatment for 5 min (20 W). For the SiO₂ coating layer, —SiMe₃ groups were introduced using hexamethyldisilazane (HMDS), deposited by placing the SiO₂ substrates in an N₂-filled chamber saturated with HMDS vapor for 36-48 h. PS (5.0, 7.5, 15, or 30 mg/mL in anhydrous toluene), crosslinked-polystyrene (CPS, 1:1 volume mixture of PS 7.0 mg/mL and 1,6-bistricholosilylhexane in toluene), and PVA (30 mg/mL in millipore water) were spin-coated onto substrates at 5000 rpm in the air (relative humidity ˜30%), and cured in a vacuum oven at 80° C. overnight. For PS-Ox coating, PS1 films were exposed to an oxygen plasma for a minimal time (5 s, 20W) before characterization and subsequent semiconductor deposition. Film thicknesses were measured by profilometry (Tencor, P10). Atomic force microscopic (AFM) images including RMS roughness were obtained using a JEOL-5200 Scanning Probe Microscope with silicon cantilevers in the tapping mode, using WinSPM Software. For capacitance measurements, metal-insulator-semiconductor (MIS) structures were fabricated by depositing gold electrodes (200 μm×200 μm) on the polymer-coated p₊-Si/SiO₂ substrates. All of the semiconducting materials were vacuum deposited at 2×10⁻⁶ Torr (˜500 Å thickness, 0.2 Å/s growth rate) while maintaining the substrate temperature at ˜50° C. Thin films of organic semiconductors were analyzed by standard wide angle θ-2θ x-ray film diffractometry (WAXRD) using monochromated Cu Kα radiation. Semiconducting films were coated with 3 nm of sputtered Au before scanning electron microscopic (SEM) imaging using a Hitachi S4500 FE microscope. For FET device fabrication, top-contact electrodes (˜50 nm) were deposited by evaporating gold (3×10⁻⁶ Torr) through a shadow mask with the channel length (L) and width (W) defined as 100 μm and 5000 μm, respectively.

Electrical Measurements. The capacitance of the bilayer dielectrics was measured on MIS structures using a Signaton probe-station equipped with a digital capacitance meter (Model 3000, GLK Instruments) and a HP4192A Impedance Analyzer. All OTFT measurements were carried out under vacuum (1×10⁻⁵ Torr) using a Keithly 6430 subfemtoammeter and a Keithly 2400 source meter, operated by a local Labview program and GPIB communication. Triaxial and/or coaxial shielding was incorporated into the probe-station to minimize the noise level. Mobilities (μ) were calculated in the saturation regime using the relationship: μₛₐₜ=(2I_{DS}L)/[WCᵢ(V_{G}−V_{T})²], where I_{DS} is the source-drain saturation current; Cᵢ is the gate dielectric capacitance (per area), V_{G} is the gate voltage, and V_{T} is the threshold voltage. The latter can be estimated as the x intercept of the linear section of the plot of V_{G} vs. (I_{DS})^{1/2}. Sze, S. M. Physics of Semiconductor Devices, 2nd Ed., John Wiley & Sons: USA, 1981.

### Example 1a

### Bilayer Dielectric Fabrication and Characterization

All of the bilayer dielectric samples were fabricated on p⁺-Si/SiO₂ (300 nm) substrates. The top polymer layer was deposited by spin-coating according to the procedure described above. The polymers employed in this study are polystyrene (PS), a crosslinked polystyrene blend (CPS), and polyvinyl alcohol (PVA). Therefore, the following dielectric structures were fabricated/investigated and are identified here as the following (FIG. 1, right): are, p⁺-Si/SiO₂ (300 nm) treated with O₂ plasma before use; HMDS, p⁺-Si/SiO₂ (300 nm) treated with HMDS vapor before use; PS1, p⁺-Si SiO₂ (300 nm)/PS (24 nm); PS2, p⁺-Si/SiO₂ (300 nm)/PS (31 nm); PS3, p⁺-Si/SiO₂ (300 nm)/PS (71 nm); PS4, p⁺-Si/SiO₂ (300 nm)/PS (150 nm); PS-Ox, p⁺-Si/SiO₂ (300 nm)/PS (24 nm) treated with O₂ plasma; CPS, p⁺-Si/SiO₂ (300 nm)/CPS (13 nm); PVA, p⁺-Si/SiO₂ (300 nm)/PVA (115 nm). These samples allow investigating the effects of a wide range of surface energies, as indexed by advancing aqueous contact angle measurement data on the bilayer-dielectrics (reported in Table 1), ranging from very hydrophilic (Bare, PS-Ox; θ<10°), to moderately hydrophilic (PVA, CPS; θ˜40°), to hydrophobic (PSn and HMDS; θ>90°). The samples offer a variety of surface chemistries and polymer thicknesses (PS1-4). Note that PS-Ox, which is prepared by exposing PS1 to an oxygen plasma, exhibits essentially the same morphology and dielectric properties as PS1, but with a far more hydrophilic surface. It will be shown that these modifications strongly affect OTFT response for most of the organic semiconductors examined.

### Example 1b

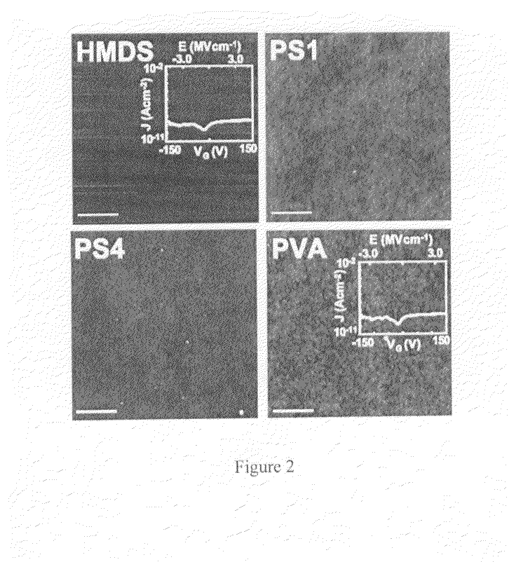

Typical leakage current densities of the surface-modified substrates are identical to that of pristine p⁺-Si/SiO₂ (Bare), <10⁻⁹A/cm² at E˜4 MV/cm, as measured in MIS structures (M=Au, 200×200 μm contact area). The insets of the AFM images in FIG. 2 show that the current density versus voltage plots for the thinnest (Bare,) and the thickest (PS4) insulators are identical. This result demonstrates that the leakage current densities at the maximum OTFT gate fields employed here (˜3.3 MV/cm) are dominated by the bottom SiO₂ layer. AFM micrographs of the bilayer films reveal that with the exception of CPS (RMS roughness ρ˜0.9 nm), all dielectric samples exhibit very similar topographies characterized by very smooth AFM morphologies with ρ=0.1˜0.3 nm, slightly larger for the thicker PSn films (Table 3). Representative AFM images are also shown in FIG. 2. Consequently, the differences among OTFT performance parameters (vide infra) can be mainly attributed to the chemical nature of the dielectric-semiconductor interface, since the dielectric surface roughness and gate leakage current are almost identical, regardless of the surface modification.

TABLE 3
Properties of the Bilayer Dielectrics Investigated in this Study
Including Top-Layer Film Thickness (D, nm), Dielectric Surface
RMS Roughness (ρ, nm), Advancing Aqueous Contact Angle (θ, °),
Effective Areal Capacitance (Cᵢ, nF/cm²), Dielectric Constant
(kₜₒₚ), and Effective Dielectric Constant (k_{eff}).

| Dielectric | D | ρ | θ | Cᵢ | kₜₒₚ | k_{eff} |
|---|---|---|---|---|---|---|
| BARE | 0 | 0.1 | <5 | 11.4 | 3.9 | 3.9 |
| HMDS | 0.4 | 0.1 | 102 | 11.4 | 2.8^{a} | 3.9 |
| PS1 | 24 | 0.2 | 92 | 10.3 | 2.5 | 3.8 |
| PS2 | 31 | 0.2 | 92 | 10.0 | 2.5 | 3.7 |
| PS3 | 71 | 0.3 | 92 | 8.5 | 2.5 | 3.6 |
| PS4 | 150 | 0.3 | 92 | 6.5 | 2.5 | 3.3 |
| PVA | 115 | 0.3 | 45 | 9.5 | 7.4 | 4.5 |
| CPS | 13 | 0.9 | 40 | 10.7 | 2.6 | 3.7 |
| PS-Oxy | 24 | 0.3 | <10 | 10.3 | 2.5 | 3.8 |

^{a}estimated for PDMS polymers (Ref 37).

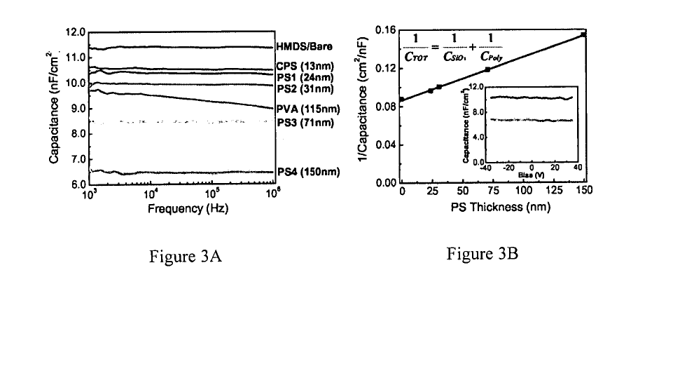

Table 3 also collects the areal capacitance (±5%) and the effective/top polymer layer dielectric constant data measured at 10 kHz for all dielectric samples. Capacitance-frequency plots (1-1000 kHz) shown in FIG. 3 demonstrate that all dielectrics, with the exception of PVA, exhibit very little dispersion, typically <3%. The Bare and HMDS dielectrics exhibit the highest capacitance of 11.4 nF/cm², resulting in an effective dielectric constant of 3.9, identical to that reported in the literature for SiO₂. A simple model of two parallel-plate capacitors in series is reasonably assumed to calculate the dielectric constant of the top polymer layer (kₜₒₚ), and the relationship (the reciprocal additive rule) is depicted in the inset of FIG. 3. The capacitance of PSn substrates gradually decreases from 10.3 (PS1) to 6.5 nF/cm² (PS4) when the top layer film thicknesses is increased from 24 to 150 nm. Note that the plot of PS layer thickness versus reciprocal bilayer capacitance is linear, with the y-intercept and slope providing the SiO₂ bottom layer capacitance (1/0.087=11.5 nF/cm²) and kₜₒₚ of the top polystyrene layer (kₜₒₚ=2.5), respectively. From the effective capacitances of PVA (9.5 nF/cm²), CPS (10.7 nF/cm²), and PS-Ox (10.3 nF/cm²), the dielectric constants of the corresponding top PVA (7.4), crosslinked PS (2.6), and PS (2.5) polymer layers can be calculated. All values are very close to the bulk dielectric constants reported in the literature.

### Example 2a

### Thin-Film Transistor Fabrication and Characterization

As discussed above, studies on OTFTs fabricated with bilayer dielectrics (and most of those using a single polymer dielectric layer) have been limited to pentacene devices. With the goal of more fully understanding structure-property relationships governing diverse organic semiconductor-dielectric interfaces, the OTFT performance characteristics of six semiconductors on nine bilayer dielectrics were analyzed. The semiconductors investigated here (FIG. 1, left) were selected to span all possible combinations of majority carrier transport type observed on untreated/HMDS-functionalized SiO₂ dielectrics and are: i) N-type. Perfluoro-copperphthalocyanine (CuFPc), α,ω-diperfluorohexylcarbonyl-quaterthiophene (DFHCO-4T), and α,ω-diperfluorohexylquaterthiophene (DFH-4T); ii) Ambipolar. α,ω-Dihexylcarbonyl-quaterthiophene (DHCO-4T); iii) P-type. α,ω-Dihexylcarbonyl-quaterthiophene (DH-4T) and pentacene (P5) (FIG. 1). Pentacene was included since it has been widely investigated and can be used to compare our measurements to literature data on similar dielectric surfaces. These semiconductor molecular structures cover a broad selection both in terms of majority carrier type, core architectural characteristics (oligothiophenes, phthalocyanine, and acene), and core substituent chemical functionalities (fluoroalkyl, alkyl, carbonyl, F, H). Furthermore, the intrinsic sensitivities of these semiconductors (especially n-type) to ambient conditions, primarily O₂ and H₂O vapor, are quite different suggesting different sensitivities to the dielectric surface chemistry and functionalities. Note that what it is meant here by air sensitivity of an n-type semiconductor is not chemical reaction with air to afford a new chemical species. Rather, physisorbed dioxygen/H₂O at grain boundaries causes electron trapping and suppression of the TFT activity. This is supported by the observation that such OTFT devices fully recover their activity if, after exposure to air, they are remeasured in vacuum.

### Example 2b

All of the present semiconductor films were grown by vapor deposition under high vacuum (˜10⁻⁶ Torr) while maintaining the substrate(gate)-insulator temperature at 50° C. DFHCO-4T films were also deposited on bilayer dielectric substrates maintained at room temperature since it was demonstrated previously that this semiconductor exhibits the greatest carrier mobility (on HMDS-treated SiO₂ dielectric) for this film deposition procedure. Note that each semiconductor film deposition on the complete range of dielectric samples was performed in a single batch to avoid variations in film growth conditions. To assess reproducibility, two different bilayer batches corresponding to two separate monolayer/polymer preparations were used for semiconductor deposition. The final “top-contact” OTFT structures (FIG. 1, center) were completed by thermal deposition of Au source/drain electrodes (50 nm thick, 200×5000 μm² wide), resulting in OTFT devices with a channel length (L) of 100 μm and a width (W) of 5000 μm. For each semiconductor, two OTFT device arrays, each containing 50 devices were fabricated from each of the two dielectric batches. The devices were immediately transferred to a locally-built vacuum probe station and maintained under dynamic vacuum overnight before electrical characterization. The device exposure time to air (<5 min) was minimized to avoid environmental film doping/deep gas absorption.

We claim:

1. A composite comprising a dielectric component comprising an inorganic oxide and an organic polymer film coupled thereto; and an organic non-acene semiconductor component coupled to said dielectric component.

2. The composite of claim 1 wherein said semiconductor component is selected from n-type oligothiophenes.

3. The composite of claim 2 wherein said film comprises a polystyrene.

4. The composite of claim 3 wherein said semiconductor component is selected from DFHCO-4T and DFH-4T.

5. The composite of claim 1 wherein said semiconductor component is selected from ambipolar oligothiophenes.

6. The composite of claim 5 wherein said semiconductor is DHCO-4T.

7. The composite of claim 1 wherein said semiconductor component is selected from p-type oligothiophenes.

8. The composite of claim 1 wherein said oxide comprises a silicon oxide.

9. A thin film transistor device comprising a dielectric component comprising an inorganic oxide and an organic polymer; and non-acene organic semiconductor component coupled to said dielectric component, said device configured with source and drain electrodes.

10. The transistor device of claim 9 wherein said polymer is selected from insulating hydrophilic and insulating hydrophobic organic polymers.

11. The transistor device of claim 10 wherein said semiconductor component is selected from n-type oligothiophenes.

12. The transistor device of claim 11 wherein said film comprises a polystyrene.

13. The transistor device of claim 12 wherein said semiconductor component is selected from DFHCO-4T and DFH-4T.

14. The transistor device of claim 9 wherein said semiconductor component is selected from ambipolar oligothiophenes.

15. The transistor device of claim 14 wherein said semiconductor is DHCO-4T.

16. The transistor device of claim 9 wherein said semiconductor component is selected from p-type oligothiophenes.

17. A method of using a dielectric organic polymer to affect charge mobility of an organic semiconductor component, said method comprising:
fabricating a thin film transistor device comprising an inorganic dielectric component and an organic semiconductor component; and
coupling an insulating organic polymer component to said inorganic dielectric component.

18. The method of claim 17 wherein said polymeric component is a polystyrene.

19. The method of claim 18 wherein said semiconductor component comprises an n-type semiconductor.

20. The method of claim 19 wherein said semiconductor component is selected from air-sensitive oligothiophenes.
